(19) United States
(12) Patent Application Publication
(10) Pub. No.: US 2012/0153374 A1
(43) Pub. Date: Jun. 21, 2012

(54) SEMICONDUCTOR DEVICE AND METHOD OF MANUFACTURING THE SAME

(75) Inventor: Jungo INABA, Yokkaichi (JP)

(73) Assignee: KABUSHIKI KAISHA TOSHIBA, Tokyo (JP)

(21) Appl. No.: 13/325,370

(22) Filed: Dec. 14, 2011

(30) Foreign Application Priority Data
Dec. 17, 2010 (JP) 2010-281649

(51) Int. Cl. H01L 29/788; H01L 21/336

(52) U.S. Cl. 257/316; 438/257; 257/E29.3; 257/E21.422

(57) ABSTRACT

A semiconductor device including a semiconductor substrate; a memory cell region formed in the semiconductor substrate and including a plurality of memory cells; a peripheral circuit region formed in the semiconductor substrate; a first element isolation trench with a first width formed in the memory cell region; a second element isolation trench with a second width greater than the first width formed in the peripheral circuit region; a first oxide film formed along an inner surface of the first element isolation trench; a first coating oxide film formed along the first oxide film and filling the first element isolation trench; a second oxide film formed along a sidewall of the second element isolation trench; a third oxide film formed above a bottom of the second element isolation trench; and a second coating oxide film formed above the third oxide film and filling the second element isolation trench.

### CROSS-REFERENCE TO RELATED APPLICATION(S)

This application is based upon and claims the benefit of priority from Japanese Patent Application No. 2010-281649, filed on, Dec. 17, 2010 the entire contents of which are incorporated herein by reference.

### FIELD

Embodiments disclosed herein generally relate to a semiconductor device provided with an element isolation structure in which element isolation trenches are filled with coating material and a method of manufacturing such semiconductor device.

### BACKGROUND

Shallow Trench Isolation (STI) scheme is typically employed in manufacturing of semiconductor devices such a flash memories to fabricate a planar and small element isolation structures. STI scheme typically involves formation of element isolation trenches into a semiconductor substrate and filling the element isolation trenches with an element isolation insulating film. With advances in microfabrication, coating materials such as SOD (Spin On Dielectric) or SOG (Spin On Glass) exhibiting outstanding gap fill capability has become a dominating choice in an STI scheme.

Coating material, however, need to be thermally treated, after being applied to the workpiece as a coating film, in order to be converted into a silicon oxide film. One of the characteristics of the coating film is its sizable shrinkage in volume after the thermal treatment. Thus, when STI scheme is employed in a peripheral circuit region of a flash memory having a relatively wider element isolation trenches as compared to, for instance, a memory cell region, the sizable volume shrinkage of the coating film exerts large stress on the element isolation trenches to cause crystal defects. Conventionally, a CVD (Chemical Vapor Deposition) film has been employed as an alternative to the coating film in filling the element isolation trenches. However, because line bending may occur as smaller patterns are formed in the memory cell region, the use of SOG film is desired which exhibits relatively better gap fill capabilities as compared to a CVD film.

### BRIEF DESCRIPTION OF THE DRAWINGS

FIG. 1 indicates a partial equivalent circuit representation of a memory cell array of a NAND flash memory according to a first embodiment;

FIG. 2A is a schematic plan view partially illustrating the layout of a memory cell region;

FIG. 2B is a schematic plan view partially illustrating the layout of a peripheral circuit region;

FIG. 3A is a schematic cross sectional view taken along line 3A-3A of FIG. 2A;

FIG. 3B is a schematic cross sectional view taken along line 3B-3B of FIG. 2A;

FIG. 4 is a schematic cross sectional view taken along line 4-4 of FIG. 2B;

FIGS. 5A, 6A, 7A, 8A, 9A, 10A, 11A, 12A, and 13A each indicate a cross sectional view of one phase of a manufacturing process flow taken along line 3B-3B of FIG. 2A;

FIGS. 5B, 6B, 7B, 8B, 9B, 1013, 11B, 12B, and 13B each indicate a cross sectional view of one phase of a manufacturing process flow taken along line 4-4 of FIG. 2B;

FIG. 14 illustrates a second embodiment and corresponds to FIG. 7B; and

FIG. 15 corresponds to FIG. 13B.

### DETAILED DESCRIPTION

In one embodiment, a semiconductor device is disclosed. The semiconductor device includes a semiconductor substrate; a memory cell region formed in the semiconductor substrate and including a plurality of memory cells; a peripheral circuit region formed in the semiconductor substrate; a first element isolation trench with a first width formed in the memory cell region; a second element isolation trench with a second width greater than the first width formed in the peripheral circuit region; a first oxide film formed along an inner surface of the first element isolation trench; a first coating oxide film formed along the first oxide film and filling the first element isolation trench; a second oxide film formed along a sidewall of an inner surface of the second element isolation trench; a third oxide film formed above a bottom of the second element isolation trench; and a second coating oxide film formed above the third oxide film and filling the second element isolation trench.

In one embodiment, a method of manufacturing a semiconductor device is disclosed. The method includes preparing a semiconductor substrate; forming a gate insulating film on a semiconductor substrate; forming a first conductive layer serving as a floating gate electrode above the gate insulating film; processing the first conductive layer, the gate insulating film and the semiconductor substrate to form a first element isolation trench with a first width in a memory cell region and to form a second element isolation trench with a second width greater than the first width in a peripheral circuit region; forming an oxide film along an inner surface of the first element isolation trench, an inner surface of the second element isolation trench, a side section of the gate insulating film, a side section of the conductive layer, and an upper surface of the conductive layer; removing the oxide film formed above a bottom of the second element isolation trench in the peripheral circuit region to expose the semiconductor substrate situated at the bottom of the second element isolation trench; removing the resist; selectively forming a deposition oxide film by chemical vapor deposition above the exposed semiconductor substrate at the bottom of the second element isolation trench; and filling the first and the second element isolation trench by forming a coating oxide film along the oxide film and the deposition oxide film.

Embodiments are described hereinafter with references to the accompanying drawings that provide illustrations of the features of the embodiments. Elements that are identical or similar are represented by identical or similar reference symbols across the figures and are not redescribed. The drawings are not drawn to scale and thus, do not reflect the actual measurements of the features such as the correlation of thickness to planar dimensions and the relative thickness of different layers.

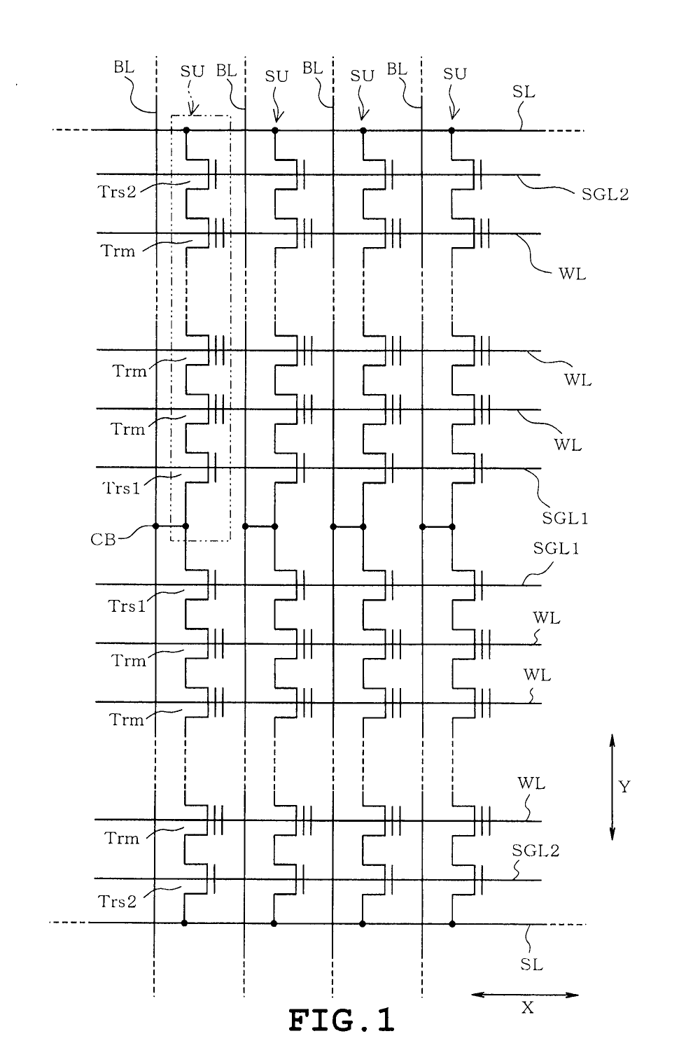

FIG. 1 is a partial equivalent circuit representation of a memory cell array formed in a memory cell region of a NAND flash memory according to a first embodiment. As can be seen in FIG. 1, the memory cell array is a collection of units of NAND cells also referred to as NAND cell unit SU arranged in rows and columns. NAND cell unit SU comprises a multiplicity of series connected memory cell transistors Trm, such as 32 in number, situated between a pair of select gate transistors Trs1 and Trs2. The neighboring memory cell transistors Trm within NAND cell unit SU share their source/drain regions.

Still referring to FIG. 1, the X-direction aligned memory cell transistors Trm are interconnected by common word line WL, whereas the X-direction aligned select gate transistors Trs1 are interconnected by common select gate line SGL1 and likewise, the X-direction aligned select gate transistors Trs2 are interconnected by common select gate line SGL2. The drain of each select gate transistor Trs1 is coupled to bit line BL by way of bit line contact CB. Bit line BL extends in the Y direction orthogonal to the X direction. The source of select gate transistor Trs2 is coupled to source line SL extending in the X-direction. As apparent from FIG. 1, the X direction indicates the direction in which word line WL extends or the width direction of the gate, whereas the Y direction indicates the direction in which bit line BL extends or the length direction of the gate.

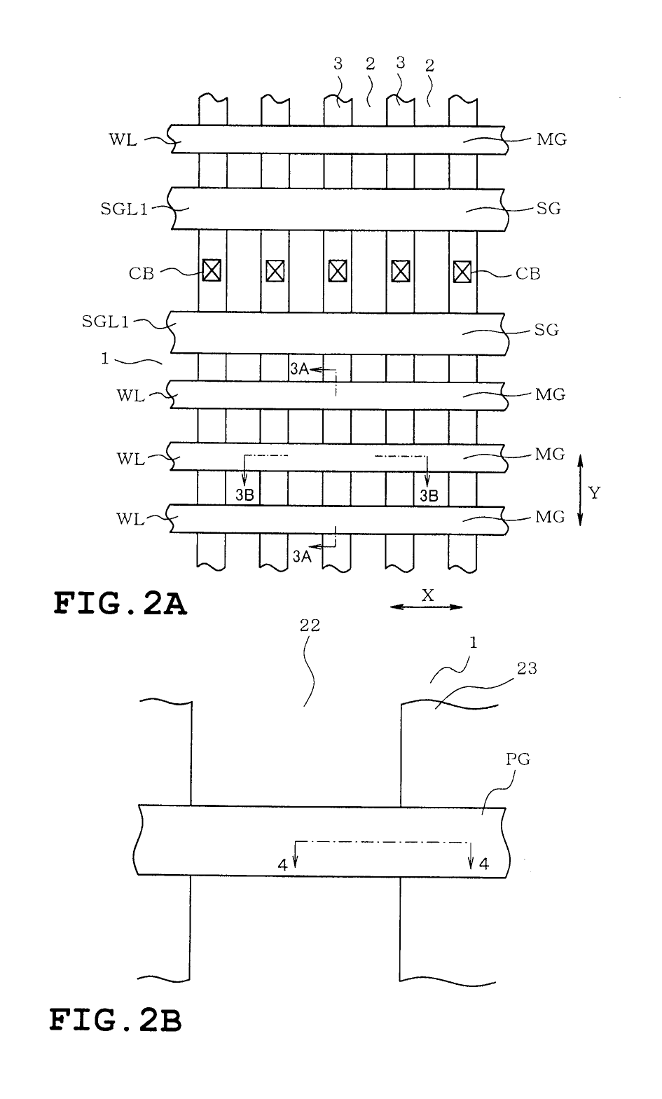

FIG. 2A provides a planar layout of memory cell region in part. As shown, multiplicity of element isolation regions employing a shallow trench isolation scheme represented as STI 2 run in the Y direction of silicon substrate 1, or more generally, the semiconductor substrate, to isolate active areas 3 by a predetermined space interval in the X direction. Multiplicity of X-directional word lines WL of memory cell transistors Trm run above STI 2 and active areas 3 so as to be orthogonal to STI 2 and active areas 3 extending in the Y direction and thus, appear as multiplicity of rows aligned in the Y direction in FIG. 2A.

Still referring to FIG. 2A, in active area 3 located between a pair of X-directional select gate lines SGL1 that are each connected to select gate transistors, bit line contact CB is formed. Gate electrode MG of a memory cell transistor Trm is formed in active area 3 where word line WL crosses over, whereas gate electrode SG of a select gate transistor is formed in active area 3 where select gate line SGL1/SGL2 crosses over.

FIG. 2B illustrates an element isolation region represented as STI 22 formed in silicon substrate 1 as was the case in the memory cell region. STI 22 delineates the element region represented as active area 23. A row of gate electrodes PG also referred to as peripheral gate electrodes are formed along the direction orthogonal to active area 23. The element isolation trenches of STI 22 in the peripheral circuit region have a wider opening as compared to those in the memory cell region. That is, the trenches of STI 2 are dimensioned at a first width, whereas the trenches of STI 22 are dimensioned at a second width greater than the first width. The first and the second widths are measurements taken at the shorter sides of the elongate element isolation trench. At the crossover site of gate electrode PG and active area 23, a transistor of a peripheral circuit is formed. Such transistor is formed in various areas of the peripheral circuit region for driving the transistors of the memory cell region and some are formed as high level voltage transistors while others are formed as low-level voltage transistors.

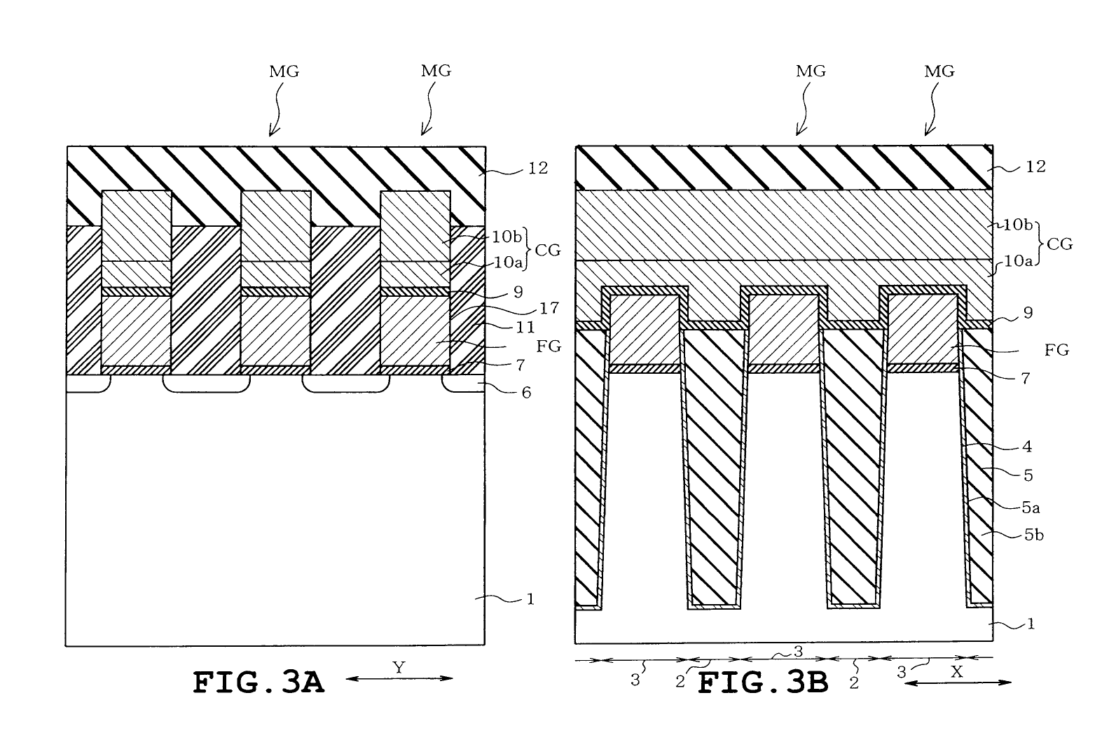

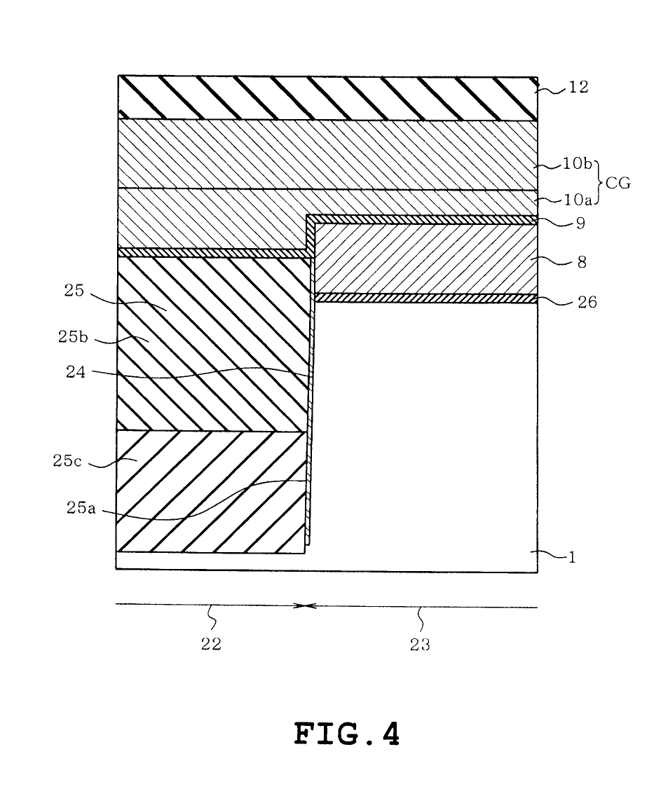

Next a description will be given on the gate electrode structures in the memory cell region and the peripheral circuit region with reference to FIGS. 3A and 3B which illustrate the memory cell region and FIG. 4 which illustrates the peripheral circuit region.

FIGS. 3A and 3B are schematic vertical cross sectional views taken along lines 3A-3A and 3B-3B of FIG. 2A. More specifically, FIG. 3A is a cross section of memory cell transistor Trm taken along bit line BL or the Y direction to schematically show the cross section of the gate electrode MG, whereas FIG. 3B is a cross section taken along word line WL or the X direction to provide an alternative view. FIG. 4 is a cross section taken along line 4-4 of FIG. 2B which is oriented along word line WL or the X direction.

As can be seen in FIGS. 3A and 3B, multiplicity of element isolation trenches 4 also referred to as first element isolation trenches are formed into silicon substrate 1. As viewed in FIG. 3B, trenches 4 are aligned in the X direction to isolate active areas 3 in the X direction. Element isolation trench 4 is filled with element isolation insulating film 5 to form element isolation region represented as STI 2. Element isolation insulating film 5 comprises liner oxide 5a also referred to as a first oxide film lined along the inner surface of element isolation trench 4 and coating oxide film 5b also referred to as a first coating oxide film formed along liner oxide 5a so as to fill element isolation trench 4.

Memory cell transistor Trm comprises an n conductive type diffusion layer 6 formed in silicon substrate 1, gate insulating film 7 formed on silicon substrate 1, and gate electrode MG formed above gate insulating film 7. Gate electrode MG comprises floating gate electrode FG serving as a charge storing layer, interelectrode insulating film 9 formed above floating gate electrode FG, and control gate electrode CG formed above interelectrode insulating film 9. Diffusion layer 6 is formed in the surface layer of silicon substrate 1 so as to be located at both sides of gate electrode MG and serves as a source/drain region.

Gate insulating film 7 is formed on silicon substrate 1 and more specifically on active areas 3 of silicon substrate 1. Gate insulating film 7 typically comprises a silicon oxide film. Floating gate electrode FG typically comprises polycrystalline silicon layer 8 serving as a conductive layer and is doped with impurities such as phosphorus. Interelectrode insulating film 9 is formed along the upper surface of element isolation insulating film 5, the upper sidewall of floating gate electrode FG, and the upper surface of floating gate electrode FG. Interelectrode insulating film 9, serving as an insulating film between the electrodes, also serves as an interpoly film and inter conductive layer film. Interelectrode insulating film 9 typically takes a laminate structure of silicon oxide film/silicon nitride film/silicon oxide film known as an ONO film with each layer typically being 3 nm to 10 nm thick.

Control gate electrode CG comprises conductive layer serving as word line WL of memory cell transistor Trm. Conductive layer comprises a laminate of polycrystalline silicon layer 10a and silicide layer 10b formed immediately on top of polycrystalline silicon layer 10a. Polycrystalline silicon layer 10a is doped with impurities such as phosphorus and silicide layer 10b which forms a silicide with either tungsten (W), cobalt (Co), nickel (Ni) or other such metals. Silicide layer 10b, according to the first embodiment, comprises nickel silicide (NiSi). In an alternative embodiment, conductive layer may be configured by silicide layer 10b alone.

FIG. 3A shows a Y-direction alignment of gate electrode MG of memory cell transistor Trm. As shown, each gate electrode MG is electrically isolated by trench 17 which is filled with inter-memory-cell insulating film 11. Inter-memory-cell insulating film 11 may comprise a silicon oxide film, employing TEOS (Tetraethyl orthosilicate) oxide film, or an insulating film with low dielectric constant.

Referring now to FIG. 4 illustrating the gate electrode structure of the peripheral circuit region, STI 22 are formed into silicon substrate 1 at predetermined interval to isolate active areas 23. STI 22 comprises element isolation trench 24 also referred to as a second element isolation trench having a second width greater than the first width of STI 2 in the memory cell region and element isolation insulating film 25 filling element isolation trench 24. Element isolation insulating film 25 comprises liner oxide 25a also referred to as a second oxide film lined along the inner surface of element isolation trench 24, bottom oxide film 25c also referred to as a third oxide film formed at the inner bottom of element isolation trench 24, and coating oxide film 25b also referred to as a second coating oxide film formed along liner oxide 25a and above bottom oxide film 25c so as to fill element isolation trench 24.

On active area 23, gate insulating film 26 thicker than gate insulating film 7 provided in memory cell transistor Trm is formed so as to serve as a gate insulating film for transistors tolerant to relatively higher voltage as compared to memory cell transistor Trm. Gate insulating film 26 typically comprises a silicon oxide film. Above gate insulating film 26, gate electrode PG is formed that comprises floating gate electrode FG, interelectrode insulating film 9, and control gate electrode CG stacked in the listed sequence as was the case in memory cell transistor Trm. Further above control gate electrode CG, interlayer insulating film 12 formed.

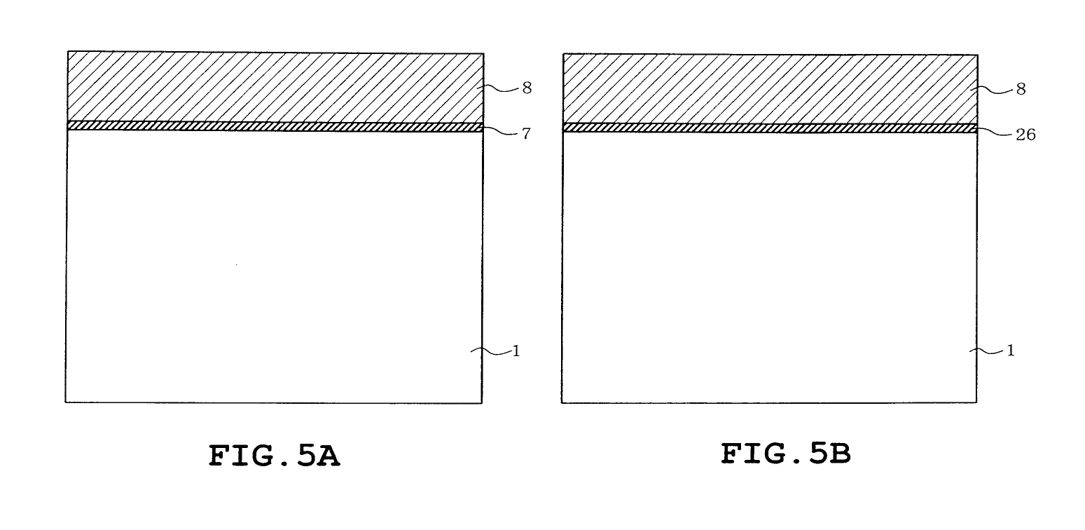

Next, a description will be given on the method of manufacturing a NAND flash memory device according to the first embodiment with reference to FIGS. 5A to 13B. FIGS. 5A, 6A, 7A, 8A, 9A, 10A, 11A, 12A, and 13A illustrate the cross sections of the memory cell region taken in FIG. 3B at different stages of the manufacturing process flow. FIGS. 5B, 6B, 7B, 8B, 9B, 10B, 11B, 12B, and 133 illustrate the cross sections of the peripheral circuit region taken in FIG. 4 at different stages of the manufacturing process flow.

As shown in FIG. 5A, gate insulating film 7 for a memory cell transistor Trm is formed above silicon substrate 1 situated in the memory cell region. Gate insulating film 7 may comprise a silicon oxide film made by thermal oxidation. As shown in FIG. 5B, gate insulating film 26 for a high level voltage transistor is formed above silicon substrate 1 situated in the area of silicon substrate 1 situated in the peripheral circuit region. Gate insulating film 26 is also formed by known thermal oxidation schemes so as to be thicker than gate insulating film 7 as described earlier.

Then, above gate insulating films 7 and 26, doped polycrystalline silicon layer 8 is formed by LPCVD (Low Pressure Chemical Vapor Deposition). Doped polycrystalline silicon layer 8 may be doped with impurities such as phosphorus (P).

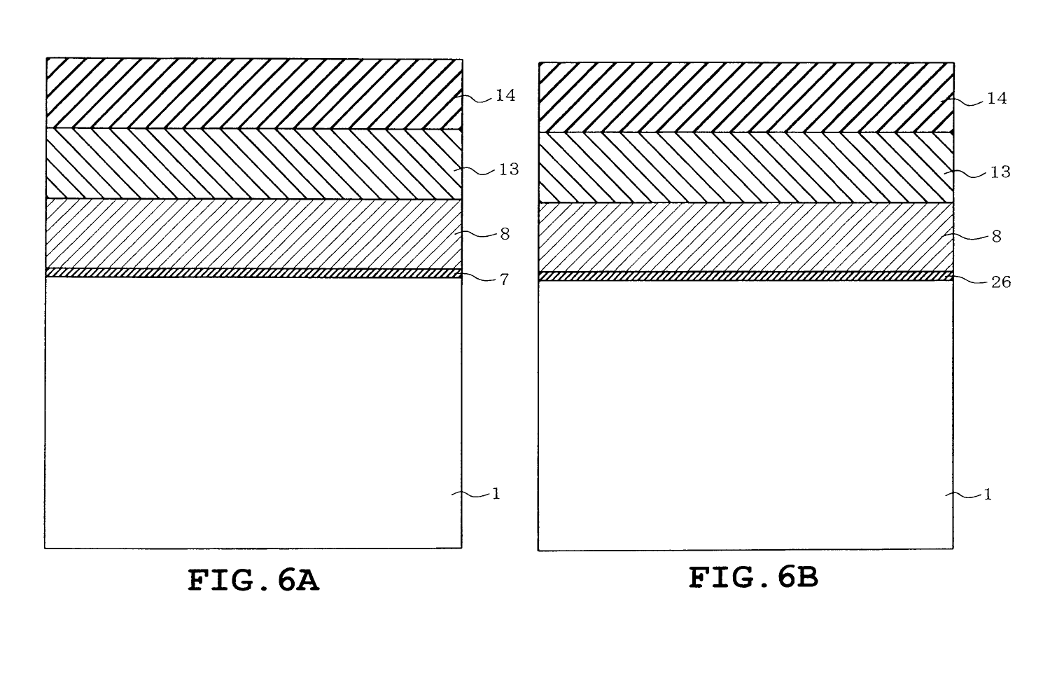

Then, as shown in FIG. 6, silicon nitride film 13 and silicon oxide film 14 are formed in the listed sequence above doped polycrystalline silicon layer 8 by CVD (Chemical Vapor Deposition).

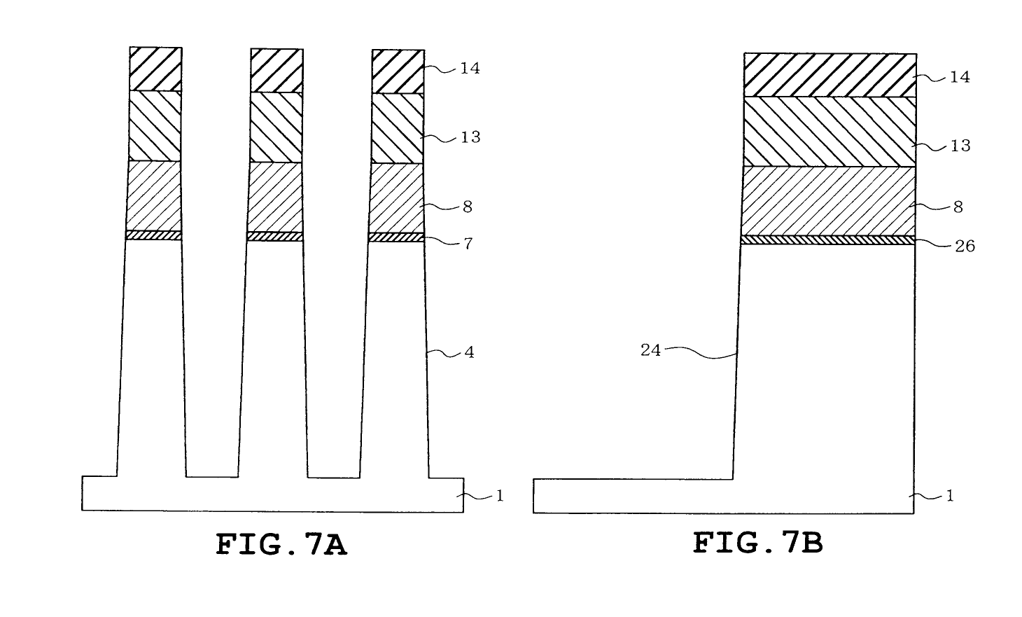

Then, a photoresist not shown is coated over silicon oxide film 14 and thereafter patterned by lithographic development. Using the patterned photoresist as a mask, silicon oxide film 14 is etched by RIE (Reactive Ion Etching). After RIE, photoresist is removed. Then, using silicon oxide film 14 as a mask, silicon nitride film 13, doped polycrystalline silicon layer 8, gate insulating film 7, and silicon substrate 1 are etched to form trenches 4 and 24 providing element isolation as shown in FIGS. 7A and 7B.

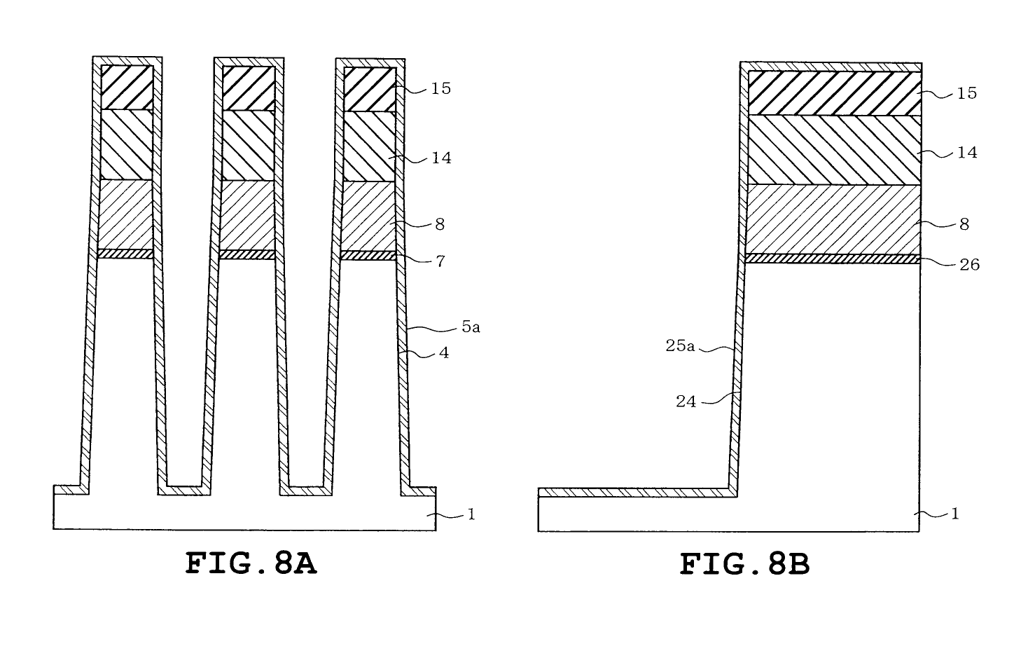

Then, as shown in FIGS. 8A and 8B, the inner surfaces of trenches 4 and 24 and the upper surfaces of active areas 3 and 23 are lined by liner oxide film 5a and 25a typically comprising a silicon oxide film, respectively by, for instance, by LPCVD.

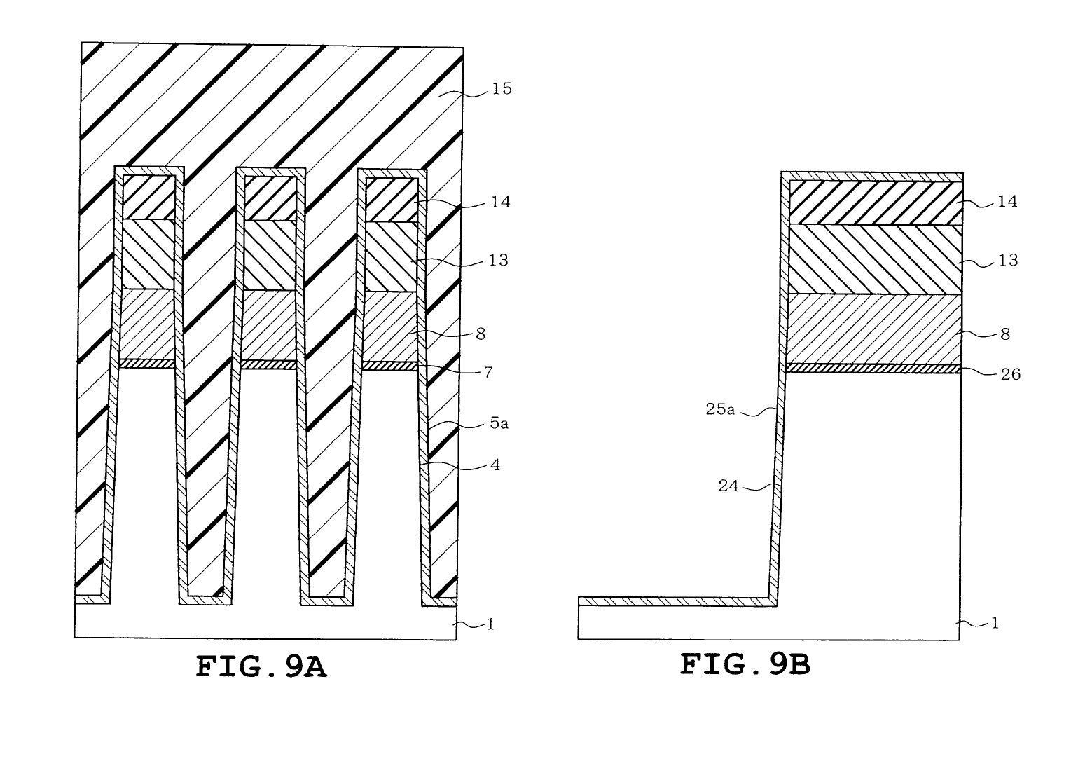

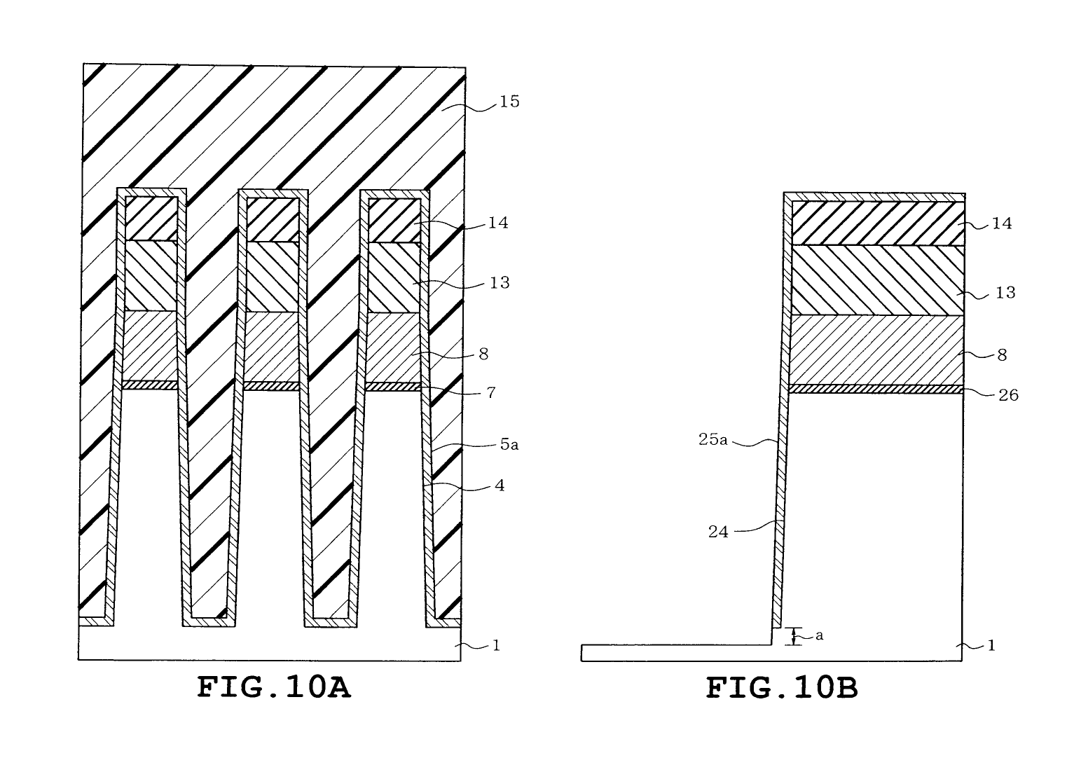

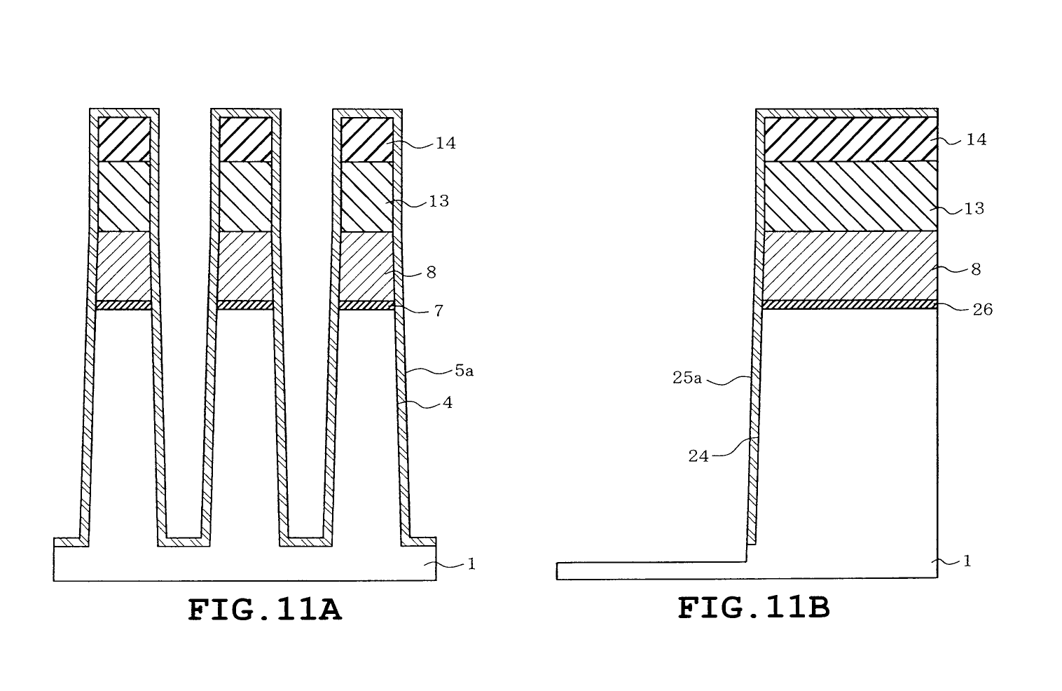

Then, after coating photoresist 15, only the peripheral circuit region is opened up by photolithography as shown in FIGS. 9A and 9B. Then, while leaving the memory cell region covered by resist 15 as shown in FIG. 10A, liner oxide film 25a at the inner bottom of second element isolation trench 24 formed in the peripheral circuit region is anisotropically etched, for instance, by RIE until silicon substrate 1 is exposed as can be seen in FIG. 10B. The etching exposes silicon substrate 1 located at the inner bottom of element isolation trench 24 as well as silicon substrate 1 located at the lowermost portion of the inner sidewall of element isolation trench 24 which is exemplified as dimension “a” in FIG. 10B. The remaining portions of the inner sidewall of element isolation trench 24, exclusive of the lowermost portion identified as dimension “a” is covered by liner oxide 25a. Then, resist 15 is removed by ashing as can be seen in FIG. 11A.

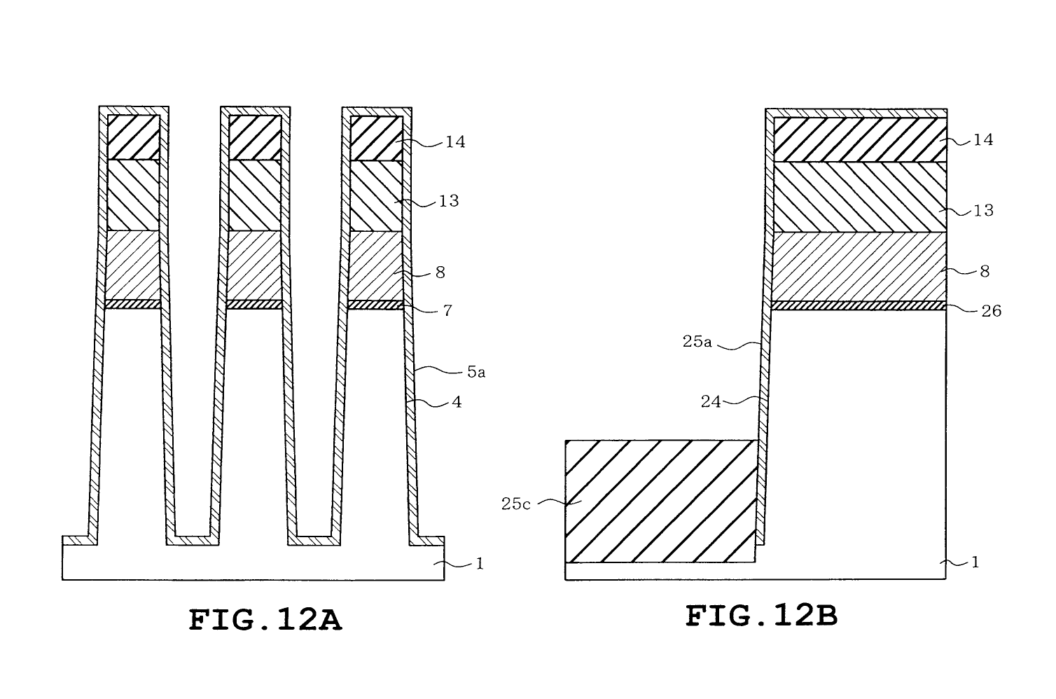

Thereafter, as shown in FIGS. 12A and 12B, silicon oxide film 25c, also referred to as the third oxide film and CVD oxide film, are selectively formed as bottom oxide 25c above silicon substrate 1 exposed at the bottom of element isolation trench 24 in the peripheral circuit region and not above liner film 5a made of silicon oxide film at the bottom of element isolation trench 4 in the memory cell region. The following is an example of an approach that may be taken to selectively form the silicon oxide film by CVD. The exemplary approach takes the advantage of the difference in the incubation time difference, that is, the difference in time taken in starting the film formation above the silicon oxide film and above silicon substrate 1. Formation of silicon oxide film is terminated before silicon oxide film starts to form above the silicon oxide film i.e. along liner oxide film 5a such that silicon oxide film 25c is formed only above silicon substrate 1.

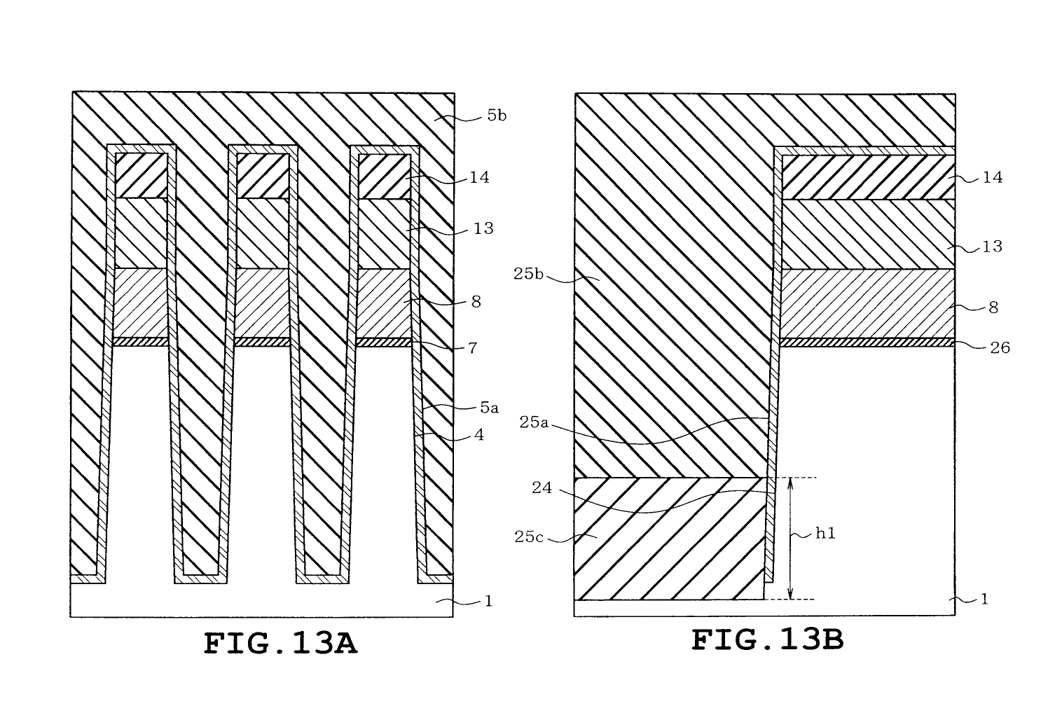

Then, as shown in FIGS. 13A and 13B, the substrate is blanketed by coating oxide film 5b and 25b, using a coating technique such as spin coating, to fill element isolation trenches 4 and 24 in the memory cell region and peripheral circuit region with coating oxide film 5b and 25b, respectively. Thereafter, coating oxide films 5b and 25b are thermally treated. The thermal treatment preferably involves a low temperature oxidation of approximately 400 degrees Celsius, for example, performed in water vapor allowing impurity removal and a high temperature densification of approximately 800 to 900 degrees Celsius, for example, in an inert atmosphere.

Coating oxide films 5b and 25b are generally susceptible to shrinking and thus, exhibit large volume shrinkage rate when subjected to thermal treatment. In contrast, bottom oxide film 25c formed by low temperature CVD within element isolation trench 24 having relatively wider opening and being situated in the peripheral circuit region exhibits relatively less volume shrinkage rate when subjected to thermal treatment as compared to coating oxide films 5b and 25b. Thus, by partially filling element isolation trench 24 having relatively wider opening with bottom oxide film 25c, amount of coating oxide film 25b filled in element isolation trench 24 can be relatively reduced. As a result, stress exerted on element isolation trench 24 can be relatively reduced to prevent crystal defects. Because element isolation trench 4 situated in the memory cell region is narrow, the device is not affected even if trench 4 is filled with coating oxide film 5b which shrinks by a relatively large volume shrinkage rate when subjected to thermal treatment.

Though not shown, the thermal treatment is followed by CMP (Chemical Mechanical Polishing) to planarize the overfilled coating oxide films 5b and 25b until silicon nitride film 14 is exposed to obtain element isolation insulating films 5 and 25. Further, element isolation films 5 and 25 residing between floating gate electrodes FG comprising polycrystalline silicon layer 8 is lowered. Then, silicon nitride film 14 remaining above polycrystalline silicon layer 8 is selectively etched away, for instance, by wet etching. Subsequently, interelectrode insulating film 9 is formed above the exposed surfaces of polycrystalline silicon layer 8 and element isolation film 5 and 25 by known processes. Thereafter, a doped polycrystalline silicon layer serving as conductive layer i.e. control gate electrode CG is formed above interelectrode insulating film 9 by CVD.

Still further, trench 17 shown in FIG. 3A is formed to isolate the gate electrodes and obtain multiple gate structures. Then, impurities are doped by ion implantation into the surface of silicon substrate 1 situated at the inner bottom of trench 17 to form diffusion layer 6. Next, trench 17 is filled with inter-memory-cell insulating film 11, serving as an insulating film between the gate structures of different cells, which is thereafter planarized and lowered. Then, on polycrystalline layer 10a, nickel silicide (NiSi) layer 10b is formed which is in turn blanket covered by interlayer insulating film 12. Thereafter, wiring not shown is established by known techniques.

In the first embodiment, the bottom portion of relatively wide element isolation trench 24 is selectively filled with bottom oxide film 25c by CVD which exhibits relatively less volume shrinkage rate as compared to coating oxide film 25b when subjected to thermal treatment. Thus, the amount of shrink-prone coating oxide film 25b filled in the relatively wide element isolation trench 24 is relatively reduced. As a result, the wide element isolation trench 24 is not affected by large stress during thermal treatment even in the presence of coating oxide film 25b which exhibits relatively large volume shrinkage rate, thereby preventing crystal defects. Because coating oxide film 5b is filled in the narrow element isolation trench 4, line bending can be prevented.

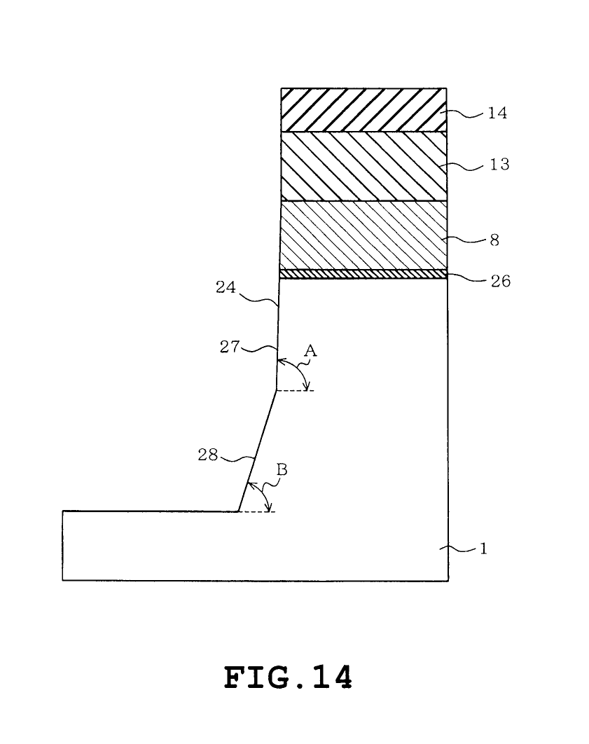

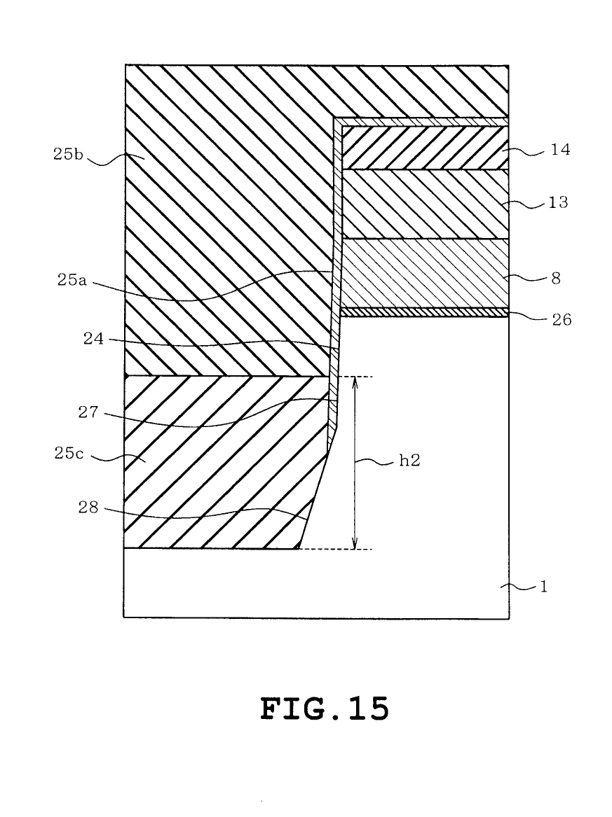

FIGS. 14 and 15 illustrate a second embodiment. Elements that are identical to those of the first embodiment are identified with identical reference symbols. As shown in FIG. 14, a slope is defined at the lower portion of the inner trench sidewall of element isolation trench 24 of the peripheral circuit region. The slope is configured to have smaller angle of inclination than any other portions of the inner trench sidewall. FIG. 14 exemplifies a case in which inner trench sidewall includes portion 27 having inclination angle A and slope 28 having inclination angle B, where inclination angle A is larger than inclination angle B, meaning that inclination angle B is smaller than inclination angle A. Slope 28 can be formed by modifying the etch recipe of RIE performed when forming element isolation trenches 4 and 24 into silicon substrate 1.

When liner oxide film 25a at the inner bottom portion of element isolation trench 24 of the peripheral circuit region is etched by RIE to expose silicon substrate 1, liner oxide film 25a formed along the surface of slope 28 is removed accordingly to expose a portion of silicon substrate 1 corresponding to slope 28 as can be seen in FIG. 15.

Then, as the result of the subsequent selective CVD formation of bottom oxide film 25c above the exposed silicon substrate 1, bottom oxide film 25c is formed along slope 28 since, the portion of silicon substrate 1 corresponding to slope 28 is exposed as mentioned earlier. Because silicon substrate 1 corresponding to slope 28 is exposed in addition to silicon substrate 1 at the bottom of element isolation trench 24, height h2 of silicon oxide film 25c formed in the second embodiment becomes higher than height h1 indicated in FIG. 13B of the first embodiment even if the duration of film formation is arranged to be identical with the first embodiment.

Apart from those described above, the features of the second embodiment are identical with the first embodiment. Thus, the second embodiment is substantially identical to the first embodiment in terms of operation and effect. The second embodiment provides slope 28 at the lower portion of the inner trench sidewall of element isolation trench 24 of the peripheral circuit region and forms bottom oxide film 25c above silicon substrate 1 exposed at the bottom portion and along slope 28 of element isolation trench 24. Accordingly, the amount of bottom oxide film 25c formed by CVD in element isolation trench 24 can be relatively increased as compared to the first embodiment to relatively reduce the amount of coating oxide film 25b filled in element isolation trench 24. Thus, the second embodiment advantageously prevents large stress from being exerted on the wider element isolation trench 24 during thermal treatment and prevents crystal defects even more effectively.

The above described embodiments may be modified or expanded as follows.

Each of the above described embodiments is directed to a NAND flash memory. However, the present disclosure may be directed to other types of semiconductor devices that include a structure in which a wide element isolation trench is filled with a coating oxide film.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor substrate;
a memory cell region formed in the semiconductor substrate and including a plurality of memory cells;
a peripheral circuit region formed in the semiconductor substrate;
a first element isolation trench with a first width formed in the memory cell region;
a second element isolation trench with a second width greater than the first width formed in the peripheral circuit region;
a first oxide film formed along an inner surface of the first element isolation trench;
a first coating oxide film formed along the first oxide film and filling the first element isolation trench;
a second oxide film formed along a sidewall of an inner surface of the second element isolation trench;
a third oxide film formed above a bottom of the second element isolation trench; and
a second coating oxide film formed above the third oxide film and filling the second element isolation trench.

2. The device according to claim 1, wherein the third oxide film is further formed along a lower edge of the sidewall of the second element isolation trench.

3. The device according to claim 1, wherein the second element isolation trench further includes a slope at a lower portion of the sidewall of the second element isolation trench, the slope having an inclination angle smaller than any other portion of the inner surface of the second element isolation trench, and wherein the third oxide film is formed above the bottom and along the slope of the second element isolation trench.

4. The device according to claim 1, wherein the first and the second oxide film comprise a silicon oxide film formed by chemical vapor deposition.

5. The device according to claim 1, wherein the first and the second coating oxide film are spin coated and comprise a thermally treated silicon oxide film.

6. The device according to claim 5, wherein the thermally treated silicon oxide film is obtained by a low temperature oxidation performed in water vapor allowing impurity removal and by a high temperature densification performed in an inert atmosphere.

7. The device according to claim 5, wherein the third oxide film exhibits a small volume shrinkage rate as compared to the first and the second coating oxide film when the first and the second coating oxide film are subjected to thermal treatment.

8. The device according to claim 7, wherein the third oxide film comprises a silicon oxide film selectively formed by chemical vapor deposition.

9. The device according to claim 1, wherein the memory cell region includes a memory cell transistor comprising a diffusion layer formed in the semiconductor substrate, a gate insulating film formed on the semiconductor substrate, and a gate electrode formed above the gate insulating film.

10. The device according to claim 9, wherein the gate electrode includes a floating gate electrode formed above the gate insulating film, an interelectrode insulating film formed above the floating gate electrode, and a control gate electrode formed above the interelectrode insulating film.

11. A method of manufacturing a semiconductor device, comprising:
forming a gate insulating film on a semiconductor substrate;
forming a first conductive layer serving as a floating gate electrode above the gate insulating film;
processing the first conductive layer, the gate insulating film and the semiconductor substrate to form a first element isolation trench with a first width in a memory cell region and to form a second element isolation trench with a second width greater than the first width in a peripheral circuit region;
forming an oxide film along an inner surface of the first element isolation trench, an inner surface of the second element isolation trench, a side section of the gate insulating film, a side section of the conductive layer, and an upper surface of the conductive layer;
removing the oxide film formed above a bottom of the second element isolation trench in the peripheral circuit region to expose the semiconductor substrate situated at the bottom of the second element isolation trench;
selectively forming a deposition oxide film by chemical vapor deposition above the exposed semiconductor substrate at the bottom of the second element isolation trench; and
filling the first and the second element isolation trench by forming a coating oxide film along the oxide film and above the deposition oxide film.

12. The method according to claim 11, wherein exposing the semiconductor substrate at the bottom of the second element isolation trench exposes the semiconductor substrate by further removing the oxide film formed along a lower edge sidewall of the inner surface of the second element isolation trench and wherein selectively forming the deposition oxide film further forms the deposition oxide film along the exposed semiconductor substrate at the lower edge sidewall of the inner surface of the second element isolation trench.

13. The method according to claim 11, wherein forming the second element isolation trench forms a slope at a lower portion of a sidewall of the inner surface of the second element isolation trench, the slope having an inclination angle smaller than any other portion of the inner surface of the second element isolation trench, and wherein exposing the semiconductor substrate exposes the semiconductor substrate situated at the slope by removing the oxide film formed along the slope, and wherein selectively forming the deposition oxide film forms the deposition oxide film along the exposed semiconductor substrate situated at the slope.

14. The method according to claim 11, wherein forming the oxide film comprises forming a silicon oxide film by chemical vapor deposition.

15. The method according to claim 11, wherein removing the oxide film above the bottom portion of the second element isolation trench in the peripheral circuit region anisotropically etches the oxide film by reactive ion etching.

16. The method according to claim 11, wherein selectively forming the deposition oxide film forms the deposition oxide film comprising a silicon oxide film by low temperature chemical vapor deposition.

17. The method according to claim 11, wherein filling the first and the second element isolation trench is followed by a thermal treatment of the coating oxide film.

18. The method according to claim 17, wherein the thermal treatment includes a low temperature oxidation performed in water vapor allowing impurity removal and by a high temperature densification performed in an inert atmosphere.

19. The method according to claim 11, wherein filling the first and the second element isolation trench is followed by planarizing the coating oxide film to obtain an element isolation insulating film, lowering the element isolation insulating film situated between the floating gate electrodes, forming an interelectrode insulating film above the floating gate electrodes and the element isolation insulating film, and forming a conducive layer serving as a control gate electrode above the interelectrode insulating film.

20. The method according to claim 19, wherein forming the conductive layer serving as the control gate electrode is followed by forming a trench for electrode isolation to obtain a plurality of gate structures, forming a diffusion layer in the semiconductor substrate situated at a bottom of the trench for electrode isolation, and forming an inter-memory-cell insulating film within the trench for electrode isolation.
